(19) United States
(12) Patent Application Publication
(10) Pub. No.: US 2017/0263689 A1
(43) Pub. Date: Sep. 14, 2017

(54) DISPLAY DEVICE

(71) Applicant: Japan Display Inc., Minato-ku (JP)

(72) Inventor: Hiromi NISHIKAWA, Minato-ku (JP)

(73) Assignee: Japan Display Inc., Minato-ku (JP)

(21) Appl. No.: 15/438,933

(22) Filed: Feb. 22, 2017

(30) Foreign Application Priority Data
Mar. 14, 2016 (JP) 2016-049853

(51) Int. Cl. H01L 27/32; H01L 51/00

(52) U.S. Cl. CPC H01L 27/3253; H01L 51/0097; H01L 2251/5338

(57) ABSTRACT

A display device includes a first substrate, a second substrate facing the first substrate, an IC chip mounted in a non-facing region of a surface of the first substrate, a terminal formed between the IC chip and an edge of the first substrate in the non-facing region, and an FPC connected to the terminal. The surface of the first substrate faces the second substrate. The non-facing region is formed between the edge of the first substrate and an edge of the second substrate. The non-facing region does not face the second substrate. The FPC includes a terminal covering portion covering the terminal and connected to the terminal, and a lateral covering portion covering a lateral portion of the non-facing region. The lateral portion is located in a direction along the edge of the second substrate with respect to the IC chip. The lateral covering portion is attached to the lateral portion.

### CROSS-REFERENCE TO RELATED APPLICATION

The present application claims priority from Japanese application JP2016-049853 filed on Mar. 14, 2016, the content of which is hereby incorporated by reference into this application.

### BACKGROUND OF THE INVENTION

1. Field of the Invention

The present invention relates to a display device.

2. Description of the Related Art

A display device such as an organic EL display device includes a first substrate provided with pixel circuits, and a second substrate facing the first substrate. The edge of the first substrate projects outward beyond the edge of the second substrate, so that a non-facing region that does not face the second substrate is formed on the first substrate. In the non-facing region, an IC chip including a driver that drives the pixel circuits is mounted, and also, terminals to which an FPC that transmits signals to be supplied to the IC chip is connected are formed.

### SUMMARY OF THE INVENTION

Now, since the non-facing region does not face the second substrate and is thin as compared with other regions, the non-facing region has a problem in that the non-facing region is likely to break during handling or during transportation. Such a problem is especially remarkable in the organic EL display device whose substrate is the first to be thinned.

The invention has been made in view of the problem described above, and it is an object of the invention to provide a display device capable of suppressing the breakage of a non-facing region.

A display device includes a first substrate, a second substrate facing the first substrate, an IC chip mounted in a non-facing region of a surface of the first substrate, a terminal formed between the IC chip and an edge of the first substrate in the non-facing region, and an FPC connected to the terminal. The surface of the first substrate faces the second substrate. The non-facing region is formed between the edge of the first substrate and an edge of the second substrate. The non-facing region does not face the second substrate. The FPC includes a terminal covering portion covering the terminal and connected to the terminal, and a lateral covering portion covering a lateral portion of the non-facing region. The lateral portion is located in a direction along the edge of the second substrate with respect to the IC chip. The lateral covering portion is attached to the lateral portion.

### BRIEF DESCRIPTION OF THE DRAWINGS

FIG. 1 is a plan view of a display device according to an embodiment of the invention.

FIG. 2 is a plan view of the display device from which an FPC is omitted.

FIG. 3 is an enlarged plan view of a main portion of the display device.

FIG. 4 is a further enlarged plan view of the main portion of the display device.

FIG. 5 is a cross-sectional view taken along line IV-IV in FIG. 3.

FIG. 6 is a plan view of a display device according to a modified example.

FIG. 7 is a plan view of a display device according to a modified example.

FIG. 8 is a plan view of a display device according to a modified example.

FIG. 9 is a plan view of a display device according to a modified example.

### DETAILED DESCRIPTION OF THE INVENTION

Hereinafter, an embodiment of the invention will be described with reference to the drawings. The disclosure is illustrative only. Appropriate modifications that will readily occur to those skilled in the art and fall within the gist of the invention are of course included in the scope of the invention. For more clarity of description, the width, thickness, shape, and the like of each part maybe schematically represented in the drawings, as compared with those in the embodiment. However, they are illustrative only and do not limit the interpretation of the invention. Moreover, in the specification and the drawings, elements similar to those described in relation to a previous drawing are denoted by the same reference numerals and signs, and a detailed description may be appropriately omitted.

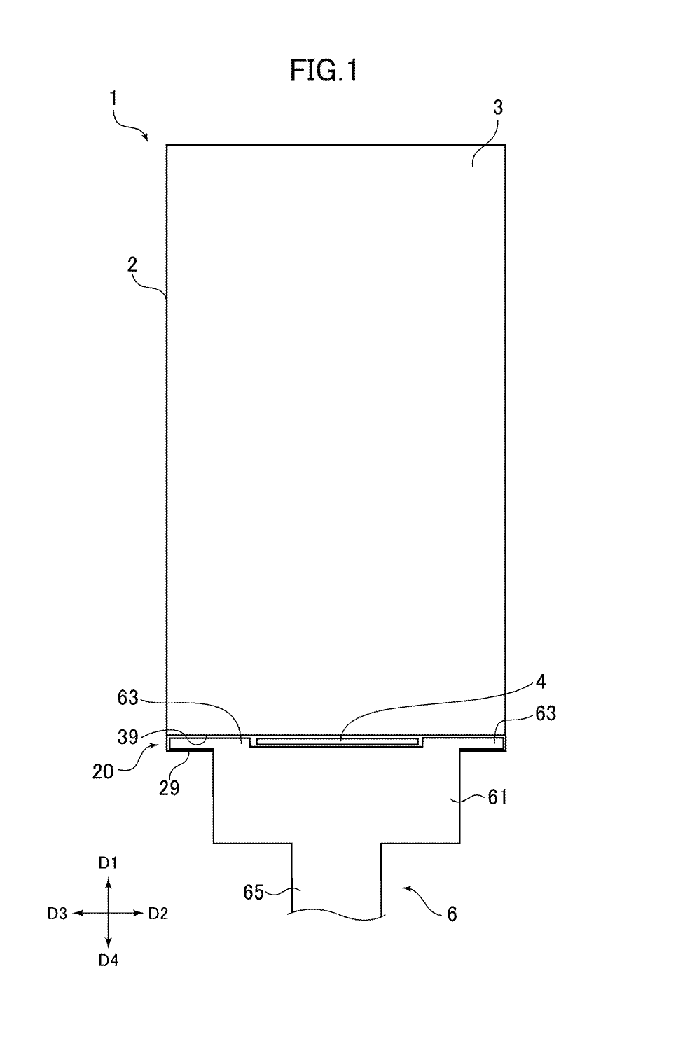

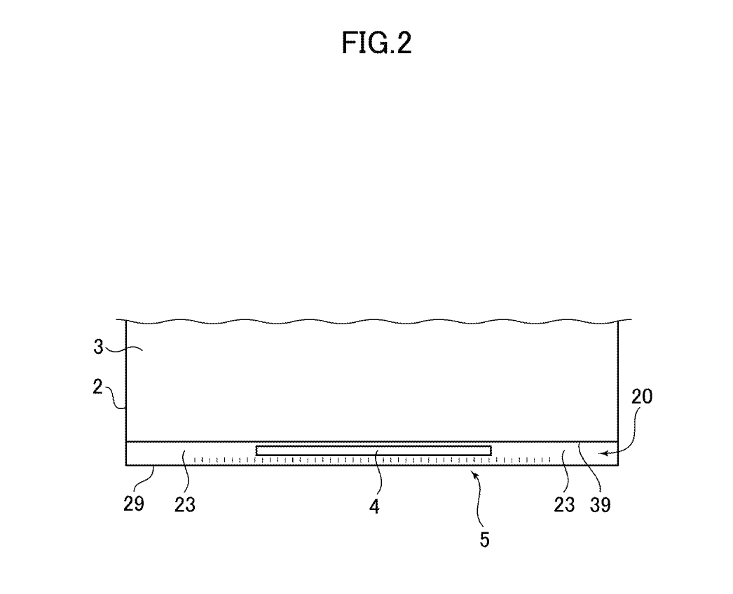

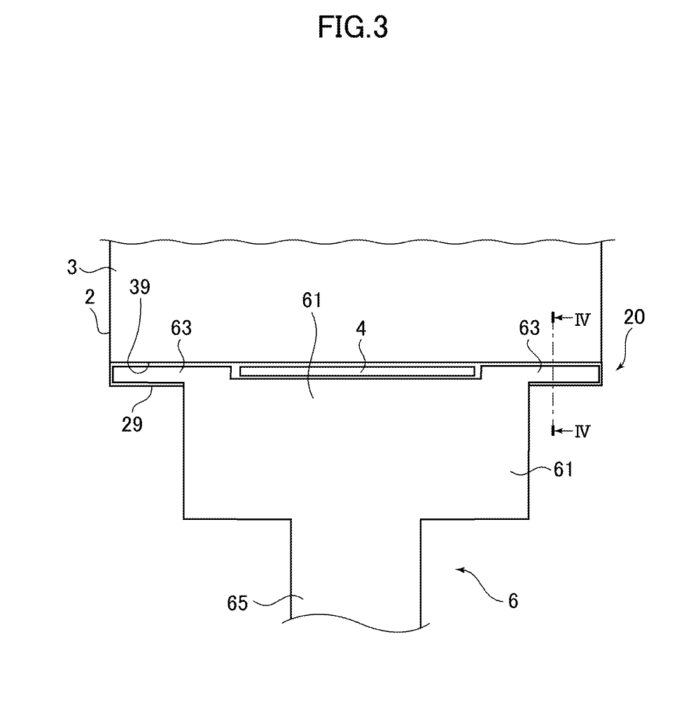

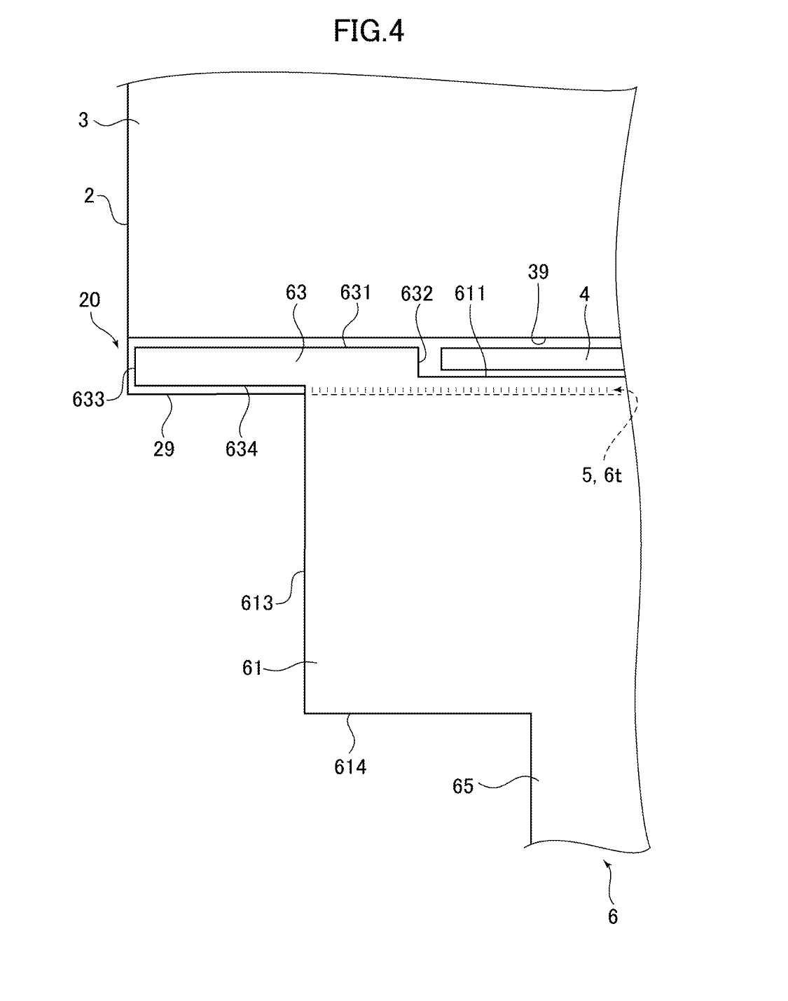

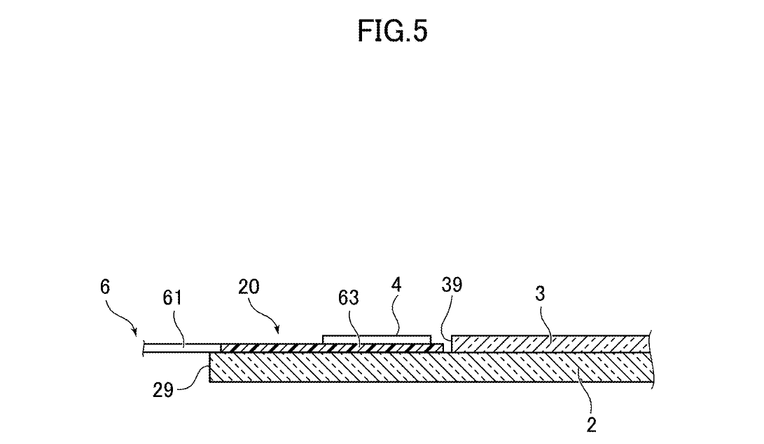

FIG. 1 is a plan view of a display device 1 according to the embodiment of the invention. FIG. 2 is a plan view of the display device 1 from which an FPC 6 is omitted. FIG. 3 is an enlarged plan view of a main portion of the display device 1. FIG. 4 is a further enlarged plan view of the main portion of the display device 1. FIG. 5 is a cross-sectional view taken along line IV-IV in FIG. 3.

The display device 1 is, for example, an organic EL display device including an organic light-emitting element (OLED). The display device 1 includes an array substrate 2 (an example of a first substrate) and a counter substrate 3 (an example of a second substrate) that faces the array substrate 2 and is bonded therewith. The array substrate 2 is, for example, a substrate in which pixel circuits arranged in a matrix, and the like are formed on a glass substrate. The counter substrate 3 is, for example, a substrate in which color filters corresponding to the pixel circuits, and the like are formed on a glass substrate.

Each of the array substrate 2 and the counter substrate 3 has a rectangular shape, and with respect to one side of the four sides, an edge 29 of the array substrate 2 projects outward beyond an edge 39 of the counter substrate 3. With this configuration, a non-facing region 20 that does not face the counter substrate 3 is formed on the array substrate 2. Specifically, the non-facing region 20 is a region of a surface, facing the counter substrate 3, of the array substrate 2, which is formed between the edge 29 of the array substrate 2 and the edge 39 of the counter substrate 3 and does not face the counter substrate 3.

In the following description, a direction (D1 in FIG. 1) of the edge 39 of the counter substrate 3 with respect to the non-facing region 20 is defined as a front direction, and a direction (D4 in FIG. 1) of the edge 29 of the array substrate 2 with respect to the non-facing region 20 is defined as a rear direction. Moreover, directions (D3 and D2 in FIG. 1) along the edge 39 of the counter substrate 3 or the edge 29 of the array substrate 2 are defined as left and right directions. Moreover, a direction of the counter substrate 3 with respect to the array substrate 2 is defined as an upper direction, and a direction of the array substrate 2 with respect to the counter substrate 3 is defined as a lower direction.

An IC chip 4 is mounted in the non-facing region 20. The IC chip 4 includes a circuit that drives the pixel circuits formed in the array substrate 2. The IC chip 4 is disposed in the central portion of the non-facing region 20 in the left and right directions. In the embodiment, lateral portions 23 (see FIG. 2) of the non-facing region 20 that are located in the respective left and right directions with respect to the IC chip 4 are portions formed of an insulating material of the surface layer of the array substrate 2. The IC chip 4 is away from the edge 39 of the counter substrate 3 in the rear direction, and away from the edge 29 of the array substrate 2 in the front direction.

A plurality of terminals 5 (see FIG. 2) arranged in the left and right directions are formed between the IC chip 4 and the edge of the array substrate 2 in the non-facing region 20. Specifically, the plurality of terminals 5 are formed in an area extended beyond the IC chip 4 in the respective left and right directions. The terminals 5 are electrically connected with the IC chip 4 via wiring lines formed within the array substrate 2.

The FPC (flexible wiring board) 6 is connected to the plurality of terminals 5 formed in the non-facing region 20. The FPC 6 transmits signals to be supplied to the IC chip 4. Hereinafter, a specific shape of the FPC 6 will be described.

The FPC 6 includes a terminal covering portion 61 that covers the plurality of terminals 5 formed in the non-facing region 20 and is connected to the terminals 5, and an extending portion 65 that extends from the terminal covering portion 61 in the rear direction. The terminal covering portion 61 has a rectangular shape having a width, in the left and right directions, comparable to that of the area where the terminals 5 are formed. A plurality of terminals 6t arranged in the left and right directions are formed on the lower surface of the terminal covering portion 61 at a front edge portion along a front edge 611 thereof. The terminals 6t are connected with the plurality of terminals 5 formed in the non-facing region 20.

The terminals 6t of the terminal covering portion 61 and the terminals 5 of the non-facing region 20 are bonded together via an adhesive material including a conductive material.

Specifically, the terminals 6t of the terminal covering portion 61 and the terminals 5 of the non-facing region 20 are bonded together by, for example, thermocompression bonding in the state where an anisotropic conductive film (ACF) is interposed between the terminals 6t and the terminals 5. Alternatively, the terminals 6t of the terminal covering portion 61 and the terminals 5 of the non-facing region 20 maybe bonded together by means of, for example, a conductive adhesive.

The FPC 6 further includes lateral covering portions 63 that cover the lateral portions 23 of the non-facing region 20 and are attached to the lateral portions 23. Since the lateral covering portions 63 of the FPC 6 are attached to the lateral portions 23 of the non-facing region 20, the breakage of the non-facing region 20 can be suppressed. In the embodiment, the lower surface of the lateral covering portion 63 is a portion formed of an insulating material of the surface layer of the FPC 6.

The lateral covering portion 63 of the FPC 6 and the lateral portion 23 of the non-facing region 20 are bonded together via an adhesive material. The adhesive material is not particularly limited. For example, an adhesive material including thermosetting resin can be applied, in which case the lateral covering portion 63 and the lateral portion 23 can be bonded together using the thermocompression bonding in bonding the terminals 6t and 5 together. Further, since the ACF includes thermosetting resin, the lateral covering portion 63 and the lateral portion 23 may be bonded together by means of the ACF, together with the terminals 6t and 5.

The lateral covering portions 63 are contiguous with the terminal covering portion 61, project from the terminal covering portion 61 in the front direction while avoiding the IC chip 4, and also project outward in the left and right directions. Specifically, the lateral covering portions 63 are contiguous with portions of the front edge portion of the terminal covering portion 61 that are located outward beyond the IC chip 4 in the left and right directions. The lateral covering portion 63 has a rectangular shape elongated in the left and right directions, and includes a front edge 631, an inner edge 632, an outer edge 633, and a rear edge 634.

The inner edge 632 of the lateral covering portion 63 is located outward beyond the IC chip 4 in the left or right direction. The inner edge 632 of the lateral covering portion 63 and the front edge 611 of the terminal covering portion 61 form an L-shape. The inner edge 632 of the lateral covering portion 63 is close to the side end of the IC chip 4, and the front edge 611 of the terminal covering portion 61 is close to the rear end of the IC chip 4. In other words, a rectangular region is cut off from the FPC 6 due to the inner edges 632 of the lateral covering portions 63 and the front edge 611 of the terminal covering portion 61, and the IC chip 4 is disposed in the cut region.

The outer edge 633 of the lateral covering portion 63 is located outward beyond a side edge 613 of the terminal covering portion 61 in the left or right direction, and is close to the end of the non-facing region 20 in the left or right direction. The rear edge 634 of the lateral covering portion 63 extending in the left and right directions is present between the outer edge 633 of the lateral covering portion 63 and the side edge 613 of the terminal covering portion 61. The rear edge 634 of the lateral covering portion 63 and the side edge 613 of the terminal covering portion 61 form an L-shape. The rear edge 634 of the lateral covering portion 63 is located beyond the edge 29 of the array substrate 2 in the front direction, and located beyond the front edge 611 of the terminal covering portion 61 in the rear direction.

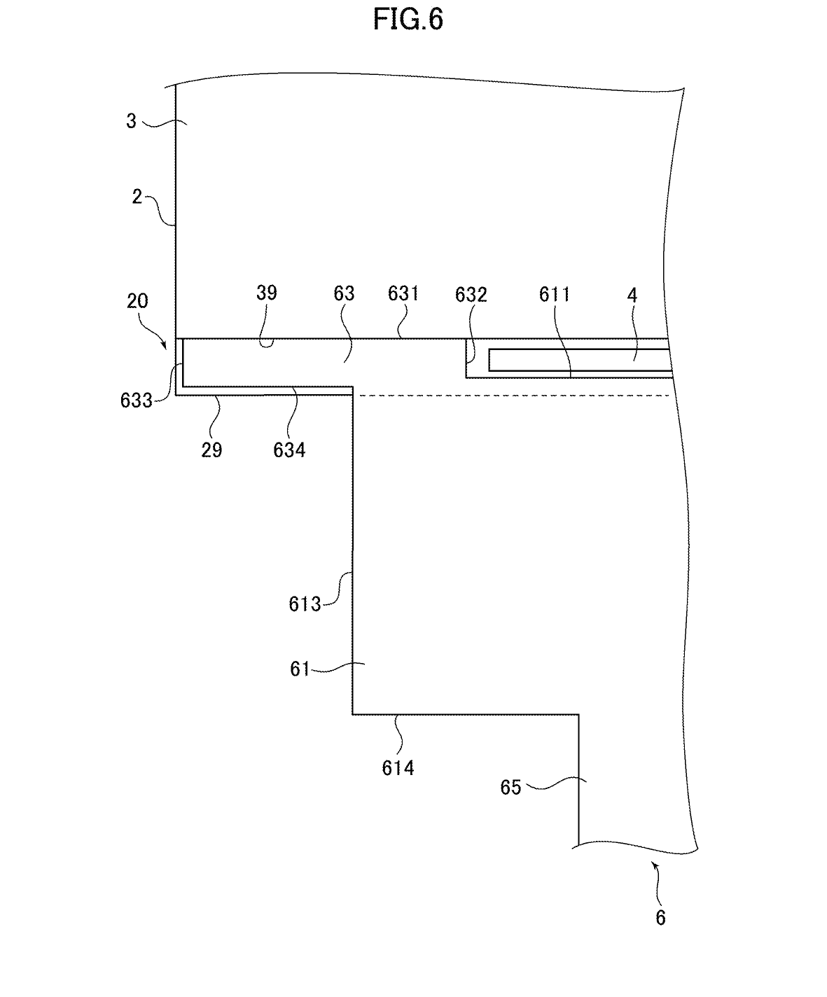

The front edge 631 of the lateral covering portion 63 is close to the edge 39 of the counter substrate 3. Specifically, the distance between the lateral covering portion 63 and the edge 39 of the counter substrate 3 is shorter than the distance between the IC chip 4 and the edge 39 of the counter substrate 3. The invention is not limited to this, and the lateral covering portion 63 and the edge 39 of the counter substrate 3 may be in contact with each other as shown in FIG. 6. Since the front edge 631 of the lateral covering portion 63 is located beyond the IC chip 4 in the front direction, the breakage of especially a portion of the non-facing region 20 that is close to the edge 39 of the counter substrate 3 can be suppressed.

An electronic component such as a capacitor or a resistor is not mounted on the upper surface of the lateral covering portion 63. That is, the lateral covering portion 63 is provided and attached to the lateral portion 23, not for the purpose of mounting an electronic component, but for the purpose of suppressing the breakage of the non-facing region 20. In JP 2004-20703 A, a portion of an FPC, where an electronic component is mounted, is not attached to a substrate, which is different from the embodiment. When the lateral covering portion 63 and the lateral portion 23 are bonded together using thermocompression bonding, it is necessary that an electronic component not be mounted on the lateral covering portion 63.

Hereinafter, modified examples will be described. Configurations redundant with those of the above embodiment are denoted by the same numerals, and a detailed description is omitted.

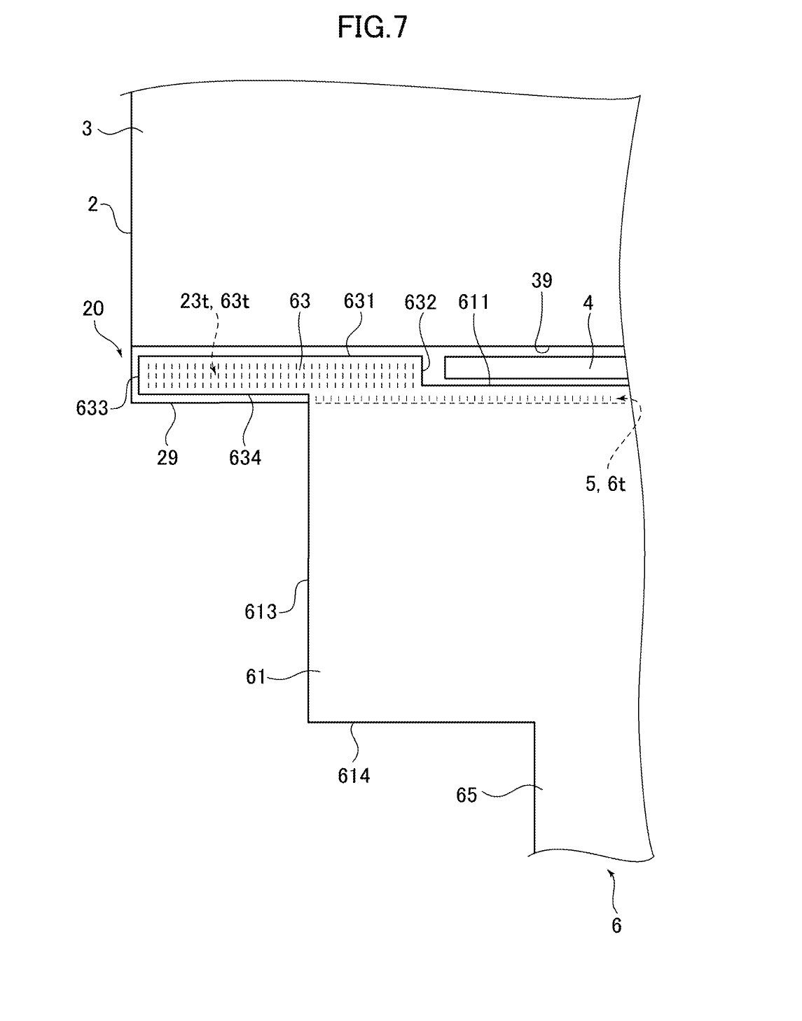

In the modified example shown in FIG. 7, a plurality of conductor pads 23t are formed on the lateral portion 23 (see FIG. 2) of the non-facing region 20. The conductor pad 23t is a so-called dummy pad, and is not electrically connected to a wiring line of the array substrate 2. The conductor pad 23t is exposed in a portion formed of the insulating material of the surface layer of the array substrate 2. The conductor pad 23t is formed by the same process as the terminal 5 of the non-facing region 20, located in the same layer as the terminal 5, and formed of the same material as the terminal 5.

On the other hand, a plurality of conductor pads 63t are formed on the lower surface of the lateral covering portion 63 of the FPC 6. The conductor pad 63t is a so-called dummy pad, and is not electrically connected to a wiring line of the FPC 6. The conductor pad 63t is exposed in a portion formed of the insulating material of the surface layer of the FPC 6. The conductor pad 63t is formed by the same process as the terminal 61t of the terminal covering portion 61, located in the same layer as the terminal 61t, and formed of the same material as the terminal 61t.

The conductor pad 23t of the lateral portion 23 and the conductor pad 63t of the lateral covering portion 63 are bonded together via the same adhesive material as the adhesive material intervening between the terminal 61t of the terminal covering portion 61 and the terminal 5 of the non-facing region 20. For example, the conductor pads 23t and 63t are bonded together by means of the ACF, together with the terminals 6t and 5. According to this bonding, the bonding strength between the lateral portion 23 and the lateral covering portion 63 can be comparable to the bonding strength between the terminals 6t and 5.

The invention is not limited to this, and either the conductor pads 23t of the lateral portion 23 or the conductor pads 63t of the lateral covering portion 63 may be omitted.

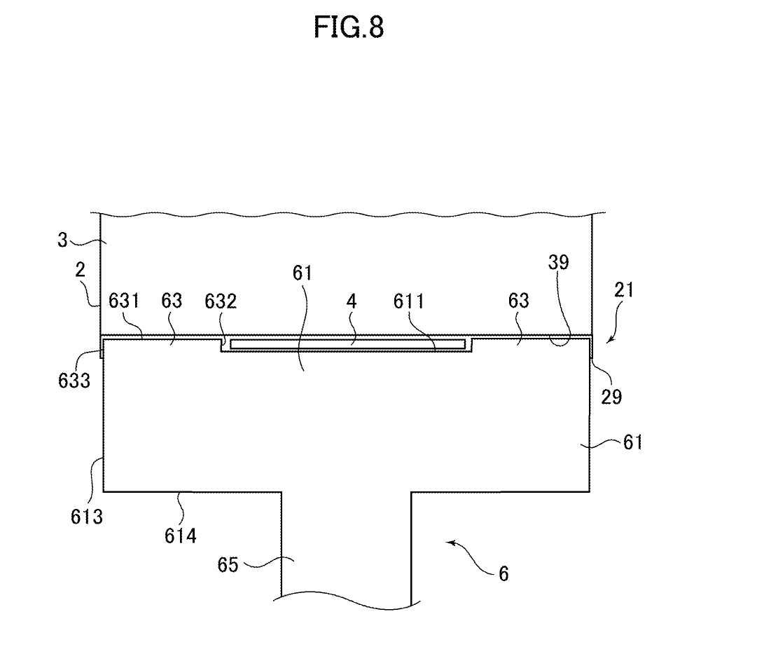

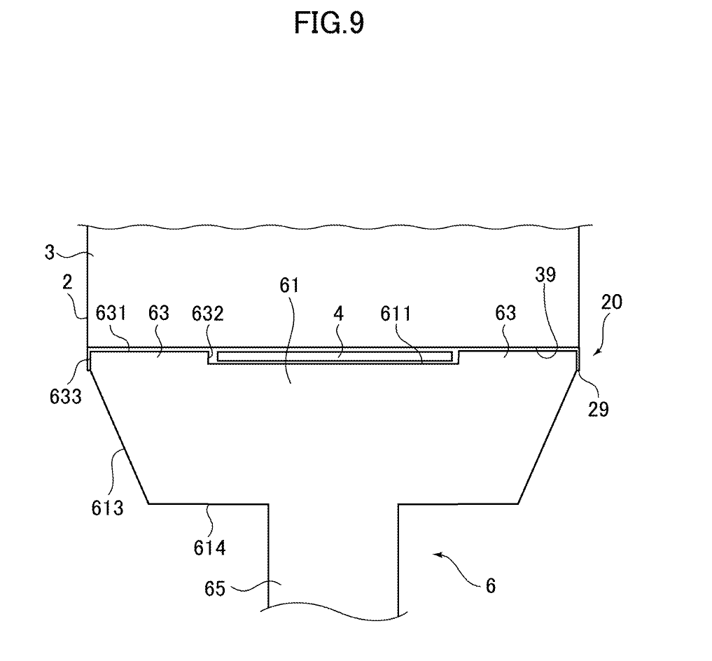

The FPC 6 can be appropriately changed in shape and the like as long as the FPC 6 includes the terminal covering portion 61, the lateral covering portion 63, and the extending portion 65. As shown in FIGS. 8 and 9 for example, the terminal covering portion 61 may project outward in the left and right directions together with the lateral covering portions 63. In FIG. 8, the side edge 613 of the terminal covering portion 61 and the outer edge 633 of the lateral covering portion 63 are formed in a straight line in the front and rear directions. In FIG. 9, the side edge 613 of the terminal covering portion 61 is inclined, from a rear edge 614 of the terminal covering portion 61 to the outer edge 633 of the lateral covering portion 63, so as to be shifted outward in the left or right direction toward the front direction. In any case, the rear edge 634 (see FIG. 4) of the lateral covering portion 63 is not formed. Since the terminal covering portion 61 also projects outward in the left and right directions as described above and thus an area where the terminal covering portion 61 is contiguous with the lateral covering portions 63 is widened, the FPC 6 can be less likely to be bent or broken.

Moreover, the FPC 6 may be provided with a coupling portion that is bridged between the two lateral covering portions 63 located in the respective left and right directions and is disposed in a gap between the IC chip 4 and the edge 39 of the counter substrate 3. In this case, a rectangular hole that is surrounded by the terminal covering portion 61, the two lateral covering portions 63, and the coupling portion is formed in the FPC 6, and the IC chip 4 is disposed inside the hole.

In the embodiment, the organic EL display device has been illustrated as an example of the disclosure. However, other application examples include all flat panel-type display devices such as a liquid crystal display device, other self-emitting-type display devices, and an electronic paper-type display device including an electrophoretic element. Moreover, it is needless to say that the invention is applicable to small or medium to large-sized display devices without particular limitation.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a first substrate;
a second substrate facing the first substrate;
an IC chip mounted in a non-facing region of a surface of the first substrate, the surface facing the second substrate, the non-facing region being formed between an edge of the first substrate and an edge of the second substrate, the non-facing region not facing the second substrate;
a terminal formed between the IC chip and the edge of the first substrate in the non-facing region; and
an FPC connected to the terminal,
the FPC including
a terminal covering portion covering the terminal and connected to the terminal, and
a lateral covering portion covering a lateral portion of the non-facing region, the lateral portion being located in a direction along the edge of the second substrate with respect to the IC chip, the lateral covering portion being attached to the lateral portion.

2. The display device according to claim 1, wherein
the terminal covering portion and the lateral covering portion are contiguous with each other.

3. The display device according to claim 1, wherein
the lateral covering portion projects from the terminal covering portion toward the edge of the second substrate while avoiding the IC chip.

4. The display device according to claim 1, wherein
the lateral covering portion projects outward beyond the terminal covering portion in the direction along the edge of the second substrate.

5. The display device according to claim 1, wherein
a distance between the lateral covering portion and the edge of the second substrate is shorter than a distance between the IC chip and the edge of the second substrate.

6. The display device according to claim 1, wherein
the lateral covering portion is in contact with the edge of the second substrate.

7. The display device according to claim 1, wherein
the same adhesive material as an adhesive material intervening between the terminal and a terminal of the terminal covering portion intervenes between the lateral portion and the lateral covering portion.

8. The display device according to claim 7, further comprising a conductor pad formed on the lateral portion and of the same material as the terminal of the non-facing region, wherein
the adhesive material intervenes between the conductor pad of the lateral portion and the lateral covering portion.

9. The display device according to claim 7, further comprising a conductor pad formed on the lateral covering portion and of the same material as the terminal of the terminal covering portion, wherein
the adhesive material intervenes between the lateral portion and the conductor pad of the lateral covering portion.

10. The display device according to claim 1, wherein
an electronic component is not mounted on the lateral covering portion.
